(19) United States
(12) Patent Application Publication
(10) Pub. No.: US 2009/0075116 A1
(43) Pub. Date: Mar. 19, 2009

(54) GRAVURE PLATE-MAKING ROLL AND METHOD OF PRODUCING THE SAME

(75) Inventors: Tatsuo Shigeta, Chiba (JP); Tsutomu Sato, Chiba (JP); Koichi Sugiyama, Kanagawa (JP); Takayuki Asano, Tokyo (JP)

Correspondence Address: MARGER JOHNSON & MCCOLLOM, P.C., 210 SW MORRISON STREET, SUITE 400, PORTLAND, OR, 97204, US

(73) Assignee: THINK LABORATORY CO., LTD., Chiba (JP)

(21) Appl. No.: 11/914,450

(22) PCT Filed: May 24, 2006
(86) PCT No.: PCT/JP2006/310302

§ 371 Date: Nov. 14, 2007

(30) Foreign Application Priority Data
Jun. 6, 2005 (JP) 2005-166067
Sep. 30, 2005 (JP) 2005-288234

(51) Int. Cl. B32B 15/20; B05D 1/36; C23C 14/34; B32B 1/08

(52) U.S. Cl. 428/674; 427/404; 204/192.12; 216/10

(57) ABSTRACT

A novel gravure engraving roll that has a surface-reinforcing coating layer being nontoxic and having no danger of pollution generation at all and that excels in printing life; and a process for producing the same. There is provided a gravure engraving roll comprising: a metal hollow roll; a copper plating layer superimposed on the surface of the hollow roll and on its surface furnished with a multiplicity of gravure cells; a metal layer superimposed on the surface of the copper plating layer; a layer of carbide of said metal superimposed on the surface of the metal layer; and a diamond-like carbon coating covering the surface of the metal carbide layer.

### TECHNICAL FIELD

The present invention relates to a gravure plate-making roll and a method of producing the same, in which a surface-reinforcing coating layer having sufficient strength can be provided without using chromium plating, in particular, to a gravure plate-making roll and a method of producing the same, in which a diamond-like carbon (DLC) layer is provided as a surface-reinforcing coating layer that replaces a chromium layer.

### BACKGROUND ART

In gravure printing, minute concave portions (gravure cells) are formed on a gravure plate-making roll (gravure cylinder) in accordance with plate-making information to produce a printing area, and the gravure cells are filled with ink so that ink is transferred to a material to be printed. In a general gravure plate-making roll, a copper plating layer (printing material) for forming a printing area is provided on the surface of a metal hollow roll made of aluminum or iron, a number of minute concave portions (gravure cells) are formed in accordance with plate-making information on the copper plating layer by etching, and then, a hard chromium layer is formed by chromium plating for enhancing printing durability of the gravure plate-making roll to form a surface-reinforcing coating layer, whereby plate-making (production of a printing area) is completed. However, highly toxic hexavalent chromium is used in a process of chromium plating, so excess cost is incurred for safely maintaining an operation, and moreover, there is a problem of an occurrence of pollution. Thus, the appearance of a surface-reinforcing layer that replaces a chromium layer is desired at present.

On the other hand, regarding the production of a gravure plate-making roll (gravure cylinder), a technique of forming a resin film on a metal hollow roll, and forming a diamond-like carbon (DLC) coating thereon to produce a gravure cylinder, thereby forming a reusable plate base metal has been proposed (Patent Document 1). However, a technique of forming a diamond-like carbon (DLC) on a copper plating surface, and using the DLC as a surface-reinforcing coating layer has not been developed (Patent Documents 2 to 4).

Patent Document 1: JP 4-282296 A

Patent Document 2: JP 11-309950 A

Patent Document 3: JP 11-327124 A

Patent Document 4: JP 2000-15770 A

### DISCLOSURE OF THE INVENTION

### Problems to be Solved by the Invention

In view of the above-mentioned problems in the related art, the inventors of the present invention studied earnestly a surface-reinforcing coating layer that replaces a chromium layer to find that the use of a combination of a tungsten carbide layer and a diamond-like carbon (DLC) layer enables a surface-reinforcing coating layer having strength comparable to that of a chromium layer and having no toxicity and possibility of the occurrence of pollution to be obtained, thereby achieving the present invention.

It is an object of the present invention to provide a novel gravure plate-making roll excellent in printing durability, which has a surface-reinforcing coating layer without toxicity and any possibility of the occurrence of pollution, and a method of producing the gravure plate-making roll.

### Means for Solving the Problems

In order to solve the above-mentioned problems, a gravure plate-making roll of the present invention includes a metal hollow roll, a copper plating layer with a number of gravure cells formed on a surface thereof, provided on a surface of the hollow roll, a metal layer provided on a surface of the copper plating layer, a metal carbide layer of the metal provided on a surface of the metal layer, and a diamond-like coating covering a surface of the metal carbide layer.

A method of producing a gravure plate-making roll of the present invention includes a process of preparing a metal hollow roll, a copper plating process of forming a copper plating layer on a surface of the hollow roll, a gravure cell formation process of forming a number of gravure cells on a surface of the copper plating layer, a metal layer formation process of forming a metal layer on a surface of the copper plating layer, a metal carbide layer formation process of forming a metal carbide layer of the metal on a surface of the metal layer, and a diamond-like carbon coating formation process of forming a diamond-like carbon coating on a surface of the metal carbide layer.

The metal carbide layer is preferably a metal carbide inclined layer, and a composition ratio of carbon in the metal carbide inclined layer is set so that a proportion of carbon increases gradually in a direction of the diamond-like carbon coating from the metal layer side.

It is preferable that a thickness of the copper plating layer is 50 to 200 μm, a depth of the gravure cells is 5 to 150 μm, a thickness of the metal layer is 0.1 to 1 μm, a thickness of the metal carbide layer is 0.1 to 1 μm, and a thickness of the diamond-like carbon coating is 0.1 to 10 μm.

It is desired that the metal layer, the metal carbide layer, preferably, a metal carbide inclined layer, and the diamond-like carbon coating each be formed by sputtering.

As the metal, it is preferable to use a metal capable of being carbonated and having high compatibility with copper.

Preferably, the metal is one or at least two kinds of metals selected from the group consisting of tungsten (W), silicon (Si), titanium (Ti), chromium (Cr), tantalum (Ta), and zirconium (Zr).

The gravure cells may be formed by etching or electronic engraving, and etching is preferable. Herein, the etching is a method of coating a plate body surface of a gravure cylinder with a sensitizing solution to perform direct burning, followed by etching, thereby forming gravure cells. The electronic engraving is a method of mechanically operating a diamond engraving needle in accordance with a digital signal to engrave gravure cells on the copper surface of the gravure cylinder.

### EFFECT OF THE INVENTION

According to the present invention, a chromium plating process can be omitted by using a diamond-like carbon (DLC) coating as a surface-reinforcing coating layer. Therefore, great effects can be exhibited in which it is not necessary to use hexavalent chromium with high toxicity, an excess cost for keeping the safety of an operation is not necessary, there is no possibility of the occurrence of pollution, and furthermore, and a diamond-like carbon (DLC) coating has strength comparable to that of a chromium layer and is excellent in printing durability.

### BRIEF DESCRIPTION OF THE DRAWINGS

FIG. 1 is an explanatory diagram schematically illustrating a production process of a gravure plate-making roll of the present invention: in which (a) is an entire cross-sectional view of a hollow roll; (b) is a partial enlarged cross-sectional view illustrating a state in which a copper plating layer is formed on the surface of the hollow roll; (c) is a partial enlarged cross-sectional view illustrating a state in which gravure cells are formed on the copper plating layer of the hollow roll; (d) is a partial enlarged cross-sectional view illustrating a state in which a tungsten carbide layer is formed on the surface of the copper plating layer of the hollow roll; (e) is a partial enlarged cross-sectional view illustrating a state in which a metal carbide layer is formed on the surface of the metal layer of the hollow roll; and (f) is a partial enlarged cross-sectional view illustrating a state in which a diamond-like carbon (DLC) coating covers the surface of the metal carbide layer of the hollow roll.

FIG. 2 is a flowchart illustrating a method of producing a gravure plate-making roll of the present invention.

FIG. 3 is an enlarged cross-sectional view of main portions of the gravure plate-making roll of the present invention.

### DESCRIPTION OF REFERENCE SYMBOLS

10: a plate base metal (a hollow roll), 10a: a gravure plate-making roll, 12: a copper plating layer, 14: a gravure cell, 16: a metal layer, 18: a metal carbide layer, preferably, a metal carbide inclined layer, 20: a diamond-like carbon (DLC) coating

### BEST MODE FOR CARRYING OUT THE INVENTION

Hereinafter, an embodiment of the present invention will be described. Illustrated examples are shown for illustrative purposes. Therefore, it is natural that they can be modified variously as long as they do not extend beyond the technical idea of the present invention.

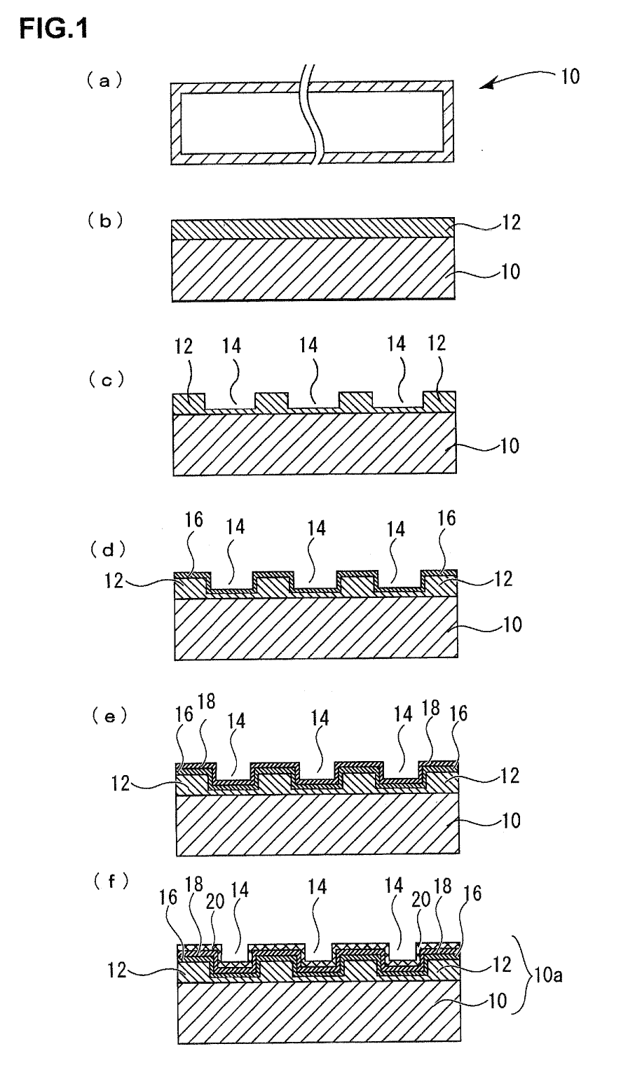

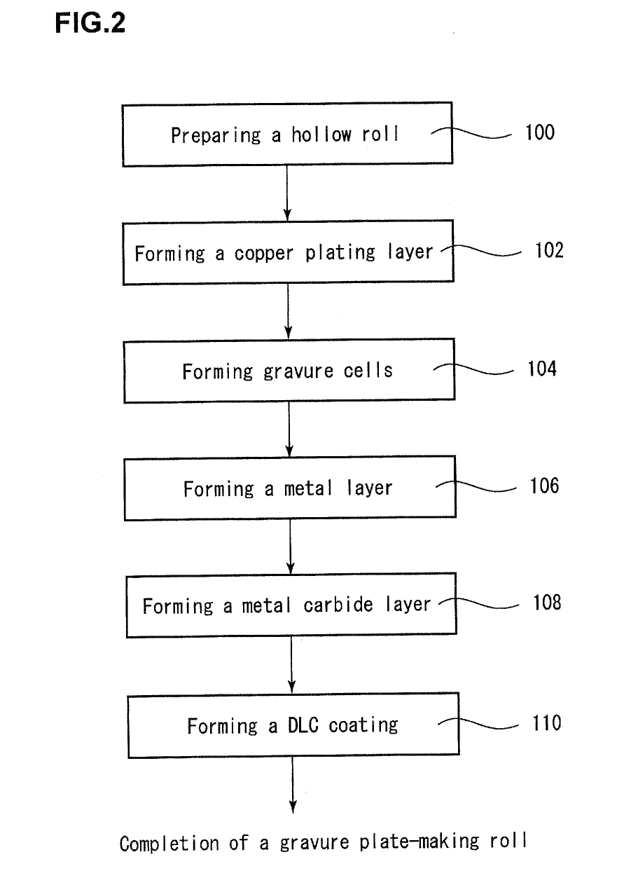

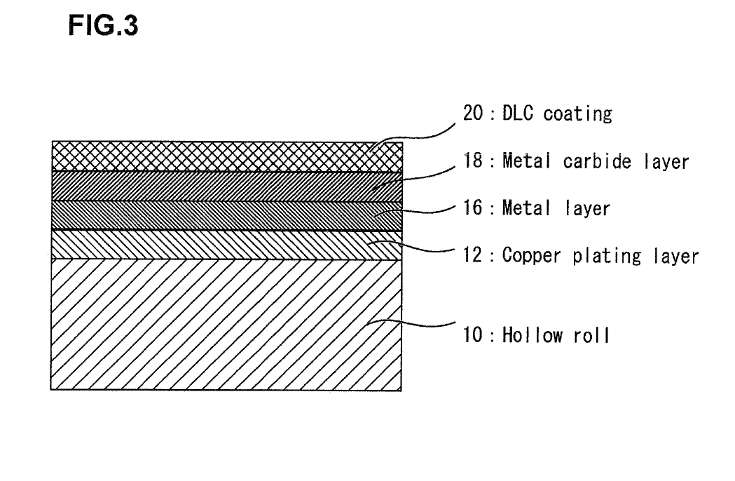

FIG. 1 is an explanatory diagram schematically illustrating a production process of a gravure plate-making roll of the present invention: (a) is an entire cross-sectional view of a hollow roll; (b) is a partial enlarged cross-sectional view illustrating a state in which a copper plating layer is formed on the surface of the hollow roll; (c) is a partial enlarged cross-sectional view illustrating a state in which gravure cells are formed on the copper plating layer of the hollow roll; (d) is a partial enlarged cross-sectional view illustrating a state in which a metal layer is formed on the surface of the copper plating layer of the hollow roll; (e) is a partial enlarged cross-sectional view illustrating a state in which a metal carbide layer is formed on the surface of the metal layer of the hollow roll; and (D is a partial enlarged cross-sectional view illustrating a state in which a diamond-like carbon (DLC) coating covers the surface of the metal carbide layer of the hollow roll. FIG. 2 is a flowchart illustrating a method of producing a gravure plate-making roll of the present invention. FIG. 3 is an enlarged cross-sectional view of main portions of the gravure plate-making roll of the present invention.

The method of the present invention will be described with reference to FIGS. 1 to 3. In FIGS. 1(a) and 3, reference numeral 10 denotes a plate base metal, and a metal hollow roll made of aluminum or iron is used for the plate base metal (Step 100 of FIG. 2). A copper plating layer 12 is formed on the surface of the hollow roll 10 by copper plating (Step 102 of FIG. 2).

On the surface of the copper plating layer 12, a number of minute concave portions (gravure cells) 14 are formed (Step 104 of FIG. 2). As a method of forming the gravure cells 14, a known method can be used, such as etching (coating a plate body surface with a sensitizing solution to perform direct burning, followed by etching, thereby forming the gravure cells 14) or electronic engraving (mechanically operating a diamond engraving needle with a digital signal to engrave the gravure cells 14 on the surface of copper), and etching is preferable.

Next, on the surface of the copper plating layer 12 (including the gravure cells 14) with the gravure cells 14 formed thereon, a metal layer 16 is formed (Step 106 of FIG. 2). Furthermore, a metal carbide layer of the metal, preferably, a metal carbide inclined layer 18 is formed on the surface of the metal layer 16 (Step 108 of FIG. 2). As a method of forming the metal layer 16 and the metal carbide layer, preferably, the metal carbide inclined layer 18, known methods such as sputtering, vapor deposition (electron beam method), ion plating, molecular beam epitaxy (MBE), laser abrasion, ion assist film-formation, or plasma CVD can be applied, and sputtering is preferable.

As the metal, a metal capable of being carbonated and having high compatibility with copper is preferable. As the metal, it is possible to use tungsten (W), silicon (Si), titanium (Ti), chromium (Cr), tantalum (Ta), and zirconium (Zr).

As the metal in the metal carbide layer, preferably, the metal carbide inclined layer 18, the same metal as that of the metal layer 16 is used. The composition ratio of carbon in the metal carbide inclined layer 18 is set so that the proportion of carbon increases gradually from the metal layer 16 side in the direction of a diamond-like carbon (DLC) coating 20 described later. That is, film formation is performed so that the composition ratio of carbon increases gradually in a proportion from 0% (in stages or in non-stages) to finally reach about 100%.

In this case, as a method of adjusting the composition ratio of carbon in the metal carbide layer, preferably, the metal carbide inclined layer 18, a known method may be used. For example, the metal carbide layer (i.e., the metal carbide inclined layer 18) can be formed, in which the composition ratios of carbon and metal are changed so that the proportion of carbon in the metal carbide layer 18 increases gradually in stages or in non-stages in the direction of the diamond-like carbon (DLC) coating 20 from the copper plating layer 12 side, for example, by sputtering (the injection amount of hydrocarbon gas such as methane gas, ethane gas, propane gas, butane gas, or acetylene gas increases gradually in stages or in non-stages in an argon gas atmosphere, using a solid metal target).

By adjusting the proportion of carbon in the metal carbide layer 18, the contact of the metal carbide layer 18 with respect to both the copper plating layer 12 and the diamond-like carbon (DLC) coating 20 can be enhanced. Furthermore, if the injection amount of hydrocarbon gas is set to be constant, a metal carbide layer in which the composition ratios of carbon and metal are set to be constant can be formed, and the metal carbide layer thus obtained is allowed to function similarly to that of the metal carbide inclined layer.

Then, on the surface of the metal carbide layer, preferably, the metal carbide inclined layer 18, the diamond-like carbon (DLC) coating 20 is formed so as to cover the surface of the metal carbide layer (Step 110 of FIG. 2). As a method of forming the diamond-like carbon (DLC) coating 20, in the same way as in the formation of the metal layer 16 and the metal carbide layer, preferably, the metal carbide inclined layer 18, a known method such as sputtering, vacuum deposition (electron beam method), ion plating, molecular beam epitaxy (MBE), laser abrasion, ion assist film formation, or plasma CVD can be applied, and sputtering is preferable.

The above-mentioned diamond-like carbon (DLC) coating 20 is covered, and is allowed to function as a surface-reinforcing coating layer, whereby a gravure plate-making roll 10a excellent in printing durability without toxicity and any possibility of the occurrence of pollution can be obtained.

Herein, according to sputtering, ions are allowed to strike a material (target material) desired to be a thin film, the material is sputtered, and the sputtered material is deposited on a substrate to produce a thin film. Sputtering is characterized in that there is no particular constraint to a target material, and a thin film can be produced with good reproducibility in a large area, etc.

According to vacuum deposition (electron beam method), a material desired to be a thin film is heated to be evaporated by the irradiation of electron beams, and the evaporated material adheres (is deposited) on a substrate to produce a thin film. Vacuum deposition is characterized in that a film formation speed is high, and the damage to a substrate is small, etc.

According to ion plating, a material desired to be a thin film is evaporated and ionized with a radio frequency (RF) (RF ion plating) or arc (arc ion plating), and deposited on a substrate to produce a thin film. The ion plating is characterized in that a film formation speed is high, and adhesion strength is large, etc.

The molecular epitaxy is a method of evaporating a raw material in an ultrasonic vacuum, and supplying the raw material to a heated substrate to form a thin film.

The laser abrasion is a method of allowing a laser pulse increased in density to be incident upon a target to allow ions to be released, thereby forming a thin film on an opposed substrate.

The ion assist film formation is a method of setting an evaporation source and an ion source in a vacuum container, and forming a film, using ions, supplementarily.

The plasma CVD is a method of decomposing a material gas using the excitation of plasma, and allowing the material gas to be deposited by reaction on a substrate, for the purpose of forming a thin film at a temperature lower than that for CVD under a reduced pressure.

### EXAMPLE

The present invention will be described more specifically by way of the following examples. It should be appreciated that these examples are shown merely for an illustrate purpose and should not be interpreted in a limiting manner.

### Examples 1-3

A gravure cylinder (aluminum hollow roll) with a circumference of 600 mm and a roll length of 1100 mm was placed in a plating bath. An anode chamber was brought close to the hollow roll up to 20 mm by an automatic slide apparatus under a computer system to allow a plating solution to overflow to immerse the hollow roll completely, whereby a copper plating layer of 80 μm was formed at 18 A/dm² and 6.0 V. A plating time was 20 minutes, and no rashes and pits were generated on the surface of plating. Thus, a uniform copper plating layer was obtained.

The copper plating layer thus formed was coated with a photosensitive film. An image was exposed to a laser to be developed, followed by burning, thereby forming a resist image. Then, dry etching such as plasma etching was conducted to engrave an image made of gravure cells. After that, a resist image was removed to form a printing plate. At this time, three hollow rolls with a gravure cell depth of 10 μm (Example 1), 18 μm (Example 2), and 30 μm (Example 3) were produced.

On an upper surface of the copper plating layer with the gravure cells formed thereon, a tungsten (W) layer was formed by sputtering. The sputtering conditions were as follows. A tungsten (W) sample: a solid tungsten target, an atmosphere: an argon gas environment, a film formation temperature: 200° C. to 300° C., a film formation time: 60 minutes, and a film formation thickness: 0.1 μm.

Next, a tungsten carbide layer was formed on the upper surface of the tungsten layer (W). The sputtering conditions were as follows. A tungsten (W) sample: a solid tungsten target, an environment: hydrocarbon gas was increased gradually in an argon gas environment, a film formation temperature: 200° C. to 300° C., a film formation time: 60 minutes, and a film formation thickness: 0.1 μm.

Furthermore, on an upper surface of tungsten carbide layer, a diamond-like carbon (DLC) coating was formed so as to cover the upper surface of the tungsten carbide by sputtering. The sputtering conditions were as follows. A DLC sample: a solid carbon target, an environment: an argon gas environment, a film formation temperature: 200° C. to 300° C., a film formation time: 150 minutes, and a film formation thickness: 1 μm. Thus, a gravure plate-making roll (gravure cylinder) was completed.

Using the above-mentioned three gravure cylinders, a printing test (printing speed: 200 m/min. and an OPP film length: 4000 m) was conducted, using oriented polypropylene film (OPP): two-axially extended polypropylene film), applying water-based ink with respect to the gravure cylinder (gravure cell depth: 10 μm) of Example 1, oil-based ink with respect to Example 2 (gravure cell depth: 18 μm), and silver paste ink with respect to Example 3 (gravure cell depth: 30 μm). Plate fogging was not caused in any of printed matters thus obtained, and transferability was satisfactory. Consequently, it was confirmed that the diamond-like carbon (DLC) coating has performance comparable to that of a conventional chromium layer, and can be used sufficiently in placed of the chromium layer.

### Examples 4-6

Three hollow rolls were produced in which the gravure cell depth was 10 μm (Example 4), 18 μm (Example 5), and 30 μm (Example 6) in the same way as in Examples 1-3. The three hollow rolls were treated to complete gravure plate-making rolls in the same way as in Examples 1-3 except that a tungsten (W) sample was changed to a silicon (Si) sample, and a printing test was conducted similarly. Consequently, printed matters without plate fogging, having satisfactory transferability, were obtained similarly. Even in these examples, it was confirmed that a diamond-like carbon (DLC) coating had performance comparable to that of a conventional chromium layer, and can be used sufficiently in place of a chromium layer. A similar experiment was conducted using titanium (Ti) and chromium (Cr) as metal samples, and it was confirmed that similar results were obtained.

1. A gravure plate-making roll, comprising:
a metal hollow roll;
a copper plating layer with a number of gravure cells formed on a surface thereof, provided on a surface of the hollow roll;
a metal layer provided on a surface of the copper plating layer;
a metal carbide layer of the metal provided on a surface of the metal layer; and
a diamond-like carbon coating covering a surface of the metal carbide layer.

2. The gravure plate-making roll according to claim 1, wherein the metal carbide layer is a metal carbide inclined layer, and a composition ratio of carbon in the metal carbide inclined layer is set so that a proportion of carbon increases gradually in a direction of the diamond-like carbon coating from the metal layer side.

3. The gravure plate-making roll according to claim l, wherein a thickness of the copper plating layer is 50 to 200 μm, a depth of the gravure cells is 5 to 150 μm, a thickness of the metal layer is 0.1 to 1 μm, a thickness of the metal carbide layer is 0.1 to 1 μm, and a thickness of the diamond-like carbon coating is 0.1 to 10 μm.

4. The gravure plate-making roll according to claim 1, wherein the metal is capable of being carbonated and has high compatibility with copper.

5. The gravure plate-making roll according to claim 1, wherein the metal is one or at least two kinds of metals selected from the group consisting of tungsten (W), silicon (Si), titanium (Ti), chromium (Cr), tantalum (Ta), and zirconium (Zr).

6. A method of producing a gravure plate-making roll, comprising steps of:
preparing a metal hollow roll;
forming a copper plating layer on a surface of the hollow roll;
forming a number of gravure cells on a surface of the copper plating layer;
forming a metal layer on a surface of the copper plating layer;
forming a metal carbide layer of the metal on a surface of the metal layer; and
forming a diamond-like carbon coating on a surface of the metal carbide layer.

7. The method of producing a gravure plate-making roll according to claim 6, wherein the metal carbide layer is a metal carbide inclined layer, and a composition ratio of carbon in the metal carbide inclined layer is set so that a proportion of carbon increases gradually in a direction of the diamond-like carbon coating from the metal layer side.

8. The method of producing a gravure plate-making roll according to claim 6, wherein a thickness of the copper plating layer is 50 to 200 μm, a depth of the gravure cells is 5 to 150 μm, a thickness of the metal layer is 0.1 to 1 μm, a thickness of the metal carbide layer is 0.1 to 1 μm, and a thickness of the diamond-like carbon coating is 0.1 to 10 μm.

9. The method of producing a gravure plate-making roll according to claim 6, wherein the metal layer, the metal carbide layer, and the diamond-like carbon coating are formed by sputtering, respectively.

10. The method of producing a gravure plate-making roll according to claim 6, wherein the metal is capable is being carbonated and has high compatibility with copper.

11. The method of producing a gravure plate-making roll according to claim 6, wherein the metal is one or at least two kinds of metals selected from the group consisting of tungsten (W), silicon (Si), titanium (Ti), chromium (Cr), tantalum (Ta), and zirconium (Zr).

12. The method of producing a gravure plate-making roll according to claim 6, wherein the gravure cells are formed by etching or electronic engraving.
